(19) United States
(12) Patent Application Publication
(10) Pub. No.: US 2026/0253980 A1
(43) Pub. Date: Aug. 27, 2026

(54) DEVICE FOR MEASURING THE QUANTITY OF CHARGE REMAINING IN AT LEAST ONE BATTERY, FLUID AND/OR THERMAL ENERGY METER INCLUDING SUCH A MEASUREMENT DEVICE, AND CLIPPER MODULE

(71) Applicant: Diehl Metering S.A.S., Saint Louis (FR)

(72) Inventors: Guy Bach, Waldighofen (FR); Bernard Dockwiller, Saint-Bernard (FR); Eric Perrin, Obermorschwihr (FR)

(21) Appl. No.: 19/536,317

(22) Filed: Feb. 11, 2026

(30) Foreign Application Priority Data
Feb. 26, 2025 (FR) 2501943

(51) Int. Cl. H01M 10/48; G01R 31/36; G01R 31/367; G01R 31/374; G01R 31/392

(52) U.S. Cl. CPC H01M 10/48; G01R 31/3648; G01R 31/367; G01R 31/374; G01R 31/392; H01M 10/482

(57) ABSTRACT

A device for measuring the quantity of charge remaining in at least one battery includes a DC current-DC current converter configured for extracting a quantity of charge from the battery for a measurement duration, and a microcontroller including a counter module and a processing module. The counter module is configured for counting the number of pulses of a pulse-train signal conditioned by a pulse conditioning stage. The processing module is configured, using the number of pulses obtained by the counter module, for determining the quantity of charge remaining in the at least one battery for the measurement duration. A fluid meter and/or a thermal energy meter includes the measurement device. A clipper module is also provided.

### CROSS-REFERENCE TO RELATED APPLICATION

This application claims the priority, under 35 U.S.C. § 119, of French Patent Application FR 2501943, filed Feb. 26, 2025; the prior application is herewith incorporated by reference in its entirety.

### FIELD AND BACKGROUND OF THE INVENTION

The present invention relates to the field of devices for measuring the quantity of charge remaining in at least one battery, the field of fluid and/or thermal energy meters and the field of clipper modules.

In an electronic device, it is often necessary to adapt the voltage delivered by the battery or batteries to the operating voltage of the electronic circuit. This is often done with a high efficiency DC/DC converter. For an electronic device, it can be very important to know the level of charge remaining in the battery or batteries. When the battery or batteries does/do not supply that information, which is always the case with the primary batteries, it cannot be calculated. In order to do that, the electronic circuit needs to know the initial charge of the battery or batteries from which it subtracts all the charges delivered by the battery or batteries over its entire lifetime. In order to know the charges delivered by the battery or batteries, it is usual to measure its output current and to multiply the value by the measurement period. That method requires processing resources, consumes current and is costly.

In order to measure the quantity of charge remaining in at least one battery a known solution is for example to use a shunt resistor. The current is measured with the shunt resistor associated with a high dynamic range electronic circuit, then the data is processed in real time. That processing in real time is particularly critical because it consumes energy.

U.S. Publication No. 2018180699A1 discloses a device including: a DC-DC pulse frequency modulation converter, a logic allowing the determination, on the basis of a calibration operation, of a calibration charge pulse-sampled on a battery supplying an input voltage to the pulse frequency modulation converter, a calibration current charge controlled so as to be added to a current charge of the system during at least a part of the calibration operation in order to supply an increased current charge seen by the converter, a counter for counting a number of pulses corresponding to switching events which are generated in the converter during the operation associated with an operational battery voltage, and in which the logic is configured for determining the charge sampled on the battery during the number of pulses, based at least in part on the operational voltage of the battery, the calibration charge sampled per pulse and the number of pulses. However, that device has the drawback of requiring an active electronic circuit, allowing the pulses to be counted upstream of the logic, which has the drawback of being complex and costly to implement.

### SUMMARY OF THE INVENTION

It is accordingly an object of the invention to provide a device for measuring the quantity of charge remaining in at least one battery, a fluid and/or thermal energy meter including such a measurement device, and a clipper module, which overcome at least one of the hereinafore-mentioned disadvantages of the heretofore-known devices of this general type and which allow at least the quantity of charge remaining in at least one battery to be measured while consuming little electrical energy and in a simplified manner.

With the foregoing and other objects in view there is provided, in accordance with the invention, a device for measuring the quantity of charge remaining in at least one battery comprising at least:
a switch-mode DC current-DC current converter configured for converting an input voltage coming from the at least one battery into an output voltage and supplying at one output a pulse-train signal, the DC current-DC current converter being configured for extracting a quantity of charge from the at least one battery for the measurement duration corresponding to a number of pulses of the pulse-train signal,
a control unit electrically connected to the DC current-DC current converter and including at least one microcontroller,
the at least one microcontroller includes a counter module having a counter input and the at least one microcontroller includes a processing module electrically connected to the counter module,
the measurement device furthermore includes a pulse conditioning stage electrically connected to the output and to the counter input and being configured for clipping the pulse-train signal so as to condition it in order to be compatible with the counter input,
the counter module is configured for counting the number of pulses of the pulse-train signal conditioned by the pulse conditioning stage, and
the processing module is configured for, at least using the number of pulses obtained by the counter module, determining the quantity of charge remaining in the at least one battery for the measurement duration.

With the objects of the invention in view, there is also provided a fluid and/or thermal energy meter, comprising at least the at least one battery and a device for measuring the quantity of charge remaining in the at least one battery, wherein the measurement device is configured according to the invention.

With the objects of the invention in view, there is concomitantly provided a clipper module, comprising at least the at least one battery and a device for measuring the quantity of charge remaining in the at least one battery, wherein the measurement device is configured according to the invention.

Other features which are considered as characteristic for the invention are set forth in the appended claims.

Although the invention is illustrated and described herein as embodied in a device for measuring the quantity of charge remaining in at least one battery, a fluid and/or thermal energy meter including such a measurement device, and a clipper module, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

The invention will be better understood by virtue of the description hereinafter, which relates to several preferred embodiments, given by way of non-limiting examples and explained with reference to the appended schematic drawings.

### BRIEF DESCRIPTION OF THE FIGURES

FIG. 1 is a block diagram of the measurement device according to the invention;

FIG. 2 is a diagram showing three curves illustrating the operation of the processing module according to a first possibility; and

FIG. 3 is a diagram showing three curves illustrating the operation of the processing module according to a second possibility.

### DETAILED DESCRIPTION OF THE INVENTION

Referring now to the figures of the drawings in detail, it is seen that a device for measuring the quantity of charge remaining BC in at least one battery 1 includes at least:
a switch-mode DC current-DC current converter 2 configured for converting an input voltage U1 coming from the at least one battery 1 into an output voltage U2 and supplying a pulse-train signal at an additional output S′, the DC current-DC current converter 2 being configured for extracting a quantity of charge from the at least one battery 1 for the measurement duration corresponding to a number of pulses of the pulse-train signal,
a control unit 3 electrically connected to the DC current-DC current converter 2 and including at least one microcontroller 4.

According to the invention, in the measurement device:
the at least one microcontroller 4 includes a counter module 5 having a counter input 6 and the at least one microcontroller 4 includes a processing module 7 electrically connected to the counter module 5,
the measurement device furthermore includes a pulse conditioning stage 8 electrically connected to the additional output S′ and to the counter input 6 and being configured for clipping the pulse-train signal so as to condition it in order to be compatible with the counter input 6,
the counter module 5 is configured for counting the number of pulses of the pulse-train signal conditioned by the pulse conditioning stage 8 and
the processing module 7 is configured for, at least using the number of pulses obtained by the counter module 5, determining the quantity of charge remaining BC in the at least one battery 1 for the measurement duration.

Advantageously, the present invention allows the quantity of charge remaining BC in at least one battery 1 to be measured for at least the measurement duration by simply conditioning the pulses output from the DC current-DC current converter 2 in order to use them directly by using the counter module 5 which is already originally present in the microcontroller 4. Thus, by choosing a microcontroller 4 originally including the counter module 5, the pulse conditioning stage 8 just needs to be added and the processing module 7 of the microcontroller 4 suitably configured in order to measure the quantity of charge remaining BC in at least one battery 1 for the measurement duration. By virtue of the invention, this results in a limited energy consumption and a simplification of the measurement device.

Preferably, the pulse conditioning stage 8 includes at least one passive analogue circuit lacking control logic.

Advantageously, the pulse conditioning stage 8 is a simple and passive analogue circuit, which limits the manufacturing cost and the electrical consumption. A passive analogue circuit is for example understood to mean an electronic circuit which does not include its own power source nor any electronic components having a logic unit of the microcontroller type.

Preferably, the pulse conditioning stage 8 includes at least one voltage clipper.

Advantageously, the voltage clipper allows the amplitude of the pulse-train signal to be clipped at the output of the DC current-DC current converter 2.

Preferably, the processing module 7 includes a calibration parameter NC pre-recorded, preferably consecutively to a calibration operation, in a memory (not shown) that the measurement device includes, which memory is electrically connected to the processing module 7, the calibration parameter NC corresponding to a number of calibration pulses NBPC for extracting a calibration quantity of charge NBCC from the at least one battery 1.

Advantageously, the calibration parameter NC allows a measurement to be obtained which is reliable by carrying out a simple calibration operation for example at the time of the manufacture of the measurement device or at a later date.

Preferably and according to a first possibility, for the measurement duration and in an iterative manner, the counter module 5 is configured so that each time that the value of the number of pulses NBP obtained reaches the number of calibration pulses NBPC, this information is communicated to the processing module 7, in such a manner that the processing module 7 is configured for subtracting the calibration quantity of charge NBCC from the preceding value of the quantity of charge remaining BC in the at least one battery 1.

Advantageously, this processing principle requires a fast reactivity of the microcontroller 4 but minimal computing resources to measure the quantity of charge remaining BC in the at least one battery 1.

The counter module 5 may also be configured for resetting the value of the number of pulses obtained to zero, when the number of calibration pulses NBPC is reached.

Preferably and according to a second possibility, for the measurement duration and in an iterative manner, the processing module 7 is configured for reading the value of the number of pulses obtained at a given time Ni, the processing module 7 is configured for dividing the number of pulses obtained at a given time Ni, to which the remainder of the division from the preceding iteration is added, by the number of calibration pulses NBPC, then subtracting from the preceding value of the quantity of charge remaining BC in the at least one battery 1 the calibration quantity of charge NBCC multiplied by the integer obtained during the division, then keeping the remainder of the division for the next iteration.

Advantageously, this processing principle requires extra computing resources from the microcontroller 4, but is not dependent on time.

Advantageously, in these aforementioned two configurations for measuring the quantity of charge remaining BC in the at least one battery 1, each pulse is taken into account without however requiring processing in real time by the processing module 7 of the microcontroller 4, as is the case in the prior art.

Preferably, the measurement device furthermore includes a wireless communications unit, preferably radiofrequency and/or NFC, electrically connected to the control unit 3.

Advantageously, the wireless communications unit allows wireless communications with the outside of the measurement device and/or vice versa in order to at least allow the reading of the quantity of charge remaining BC in the at least one battery 1 and, as the case may be, allow the writing or the reading of the calibration parameter NC.

Preferably, the measurement device furthermore includes a human-machine interface electrically connected to the control unit 3.

Advantageously, the human-machine interface allows communication to the outside of the measurement device and/or vice versa in order to at least allow the reading of the quantity of charge remaining BC in the at least one battery 1 and, as the case may be, to allow the writing or the reading of the calibration parameter NC.

The invention also relates to a fluid and/or thermal energy meter including at least the at least one battery 1 and a device for measuring the quantity of charge remaining BC in the at least one battery 1, wherein the measurement device is configured according to the invention and such as previously described.

Advantageously, the measurement device according to the invention is notably applicable in the field of fluid meters and/or the field of thermal energy meters. The invention is not of course limited to these fields of application.

The invention also relates to a clipper module including at least the at least one battery 1 and a device for measuring the quantity of charge remaining BC in the at least one battery 1, wherein the measurement device is configured according to the invention and such as previously described.

The battery 1 is a source or a generator of DC electrical current which has a nominal voltage equal to the input voltage U1. One or more batteries 1 may be connected to the DC current-DC current converter 2. The battery 1 does not form part of the measurement device according to the invention but is connected to an input E of the DC current-DC current converter 2.

The function of the switch-mode DC current-DC current converter 2 is to transform the value of the input voltage U1 coming from the battery 1 into an output voltage U2. The switch-mode DC current-DC current converter 2 includes the input E electrically connected to the battery or batteries 1. It furthermore includes the chip of the DC/DC converter 2′ which includes the additional output S′ electrically connected to the pulse conditioning stage 8 and furthermore to an inductor 9 and a capacitor 10 upstream of the control unit 3. The DC current-DC current converter 2 is electrically connected to the control unit 3 via the output S.

The output voltage U2 at the output S of the DC current-DC current converter 2 is chosen so as to be adapted to the characteristics of the control unit 3. The output voltage U2 is preferably lower than the input voltage U1. The DC current-DC current converter 2 preferably includes at least one chip of the DC/DC converter 2′ with a switch which is switched at a predetermined frequency and creates the pulse-train signal which is supplied to the additional output S′. The number of pulses of the pulse-train signal is representative of the number of switching operations of the switch. The switch is preferably a semiconductor of the MOS or transistor type.

The control unit 3 includes at least the microcontroller 4 which includes the counter module 5 and the processing module 7.

The function of the pulse conditioning stage 8 is to condition the pulse-train signal coming from the DC current-DC current converter 2 by clipping it. The pulse conditioning stage 8 preferably includes at least one diode or two diodes connected back-to-back antiparallel.

The function of the counter module 5 is to count the number of pulses from the pulse-train signal conditioned by the pulse conditioning stage 8.

The function of the processing module 7 is to determine the quantity of charge remaining BC in the at least one battery 1 using the calibration data and notably the calibration parameter NC and the data from the counter module 5 and notably from the number of pulses obtained by the counter module 5.

The memory is electrically connected to the control unit 3 and notably to the processing module 7. The memory is preferably a non-volatile memory for example of the flash type. The memory may store data coming from the control unit 3 and/or from the communications unit and/or from the human-machine interface. The memory notably allows the calibration parameter NC to be pre-recorded for the determination of the quantity of charge remaining BC. The memory allows for example the quantity of charge remaining BC in the at least one battery 1, which has been determined by the processing module 7, to be recorded.

The function of the wireless communications unit, preferably radiofrequency and/or NFC, electrically connected to the control unit 3, is to remotely communicate data coming from the control unit 3 and/or from the memory.

The function of the human-machine interface electrically connected to the control unit 3 is to communicate with a user of the data coming from the control unit 3 and/or from the memory.

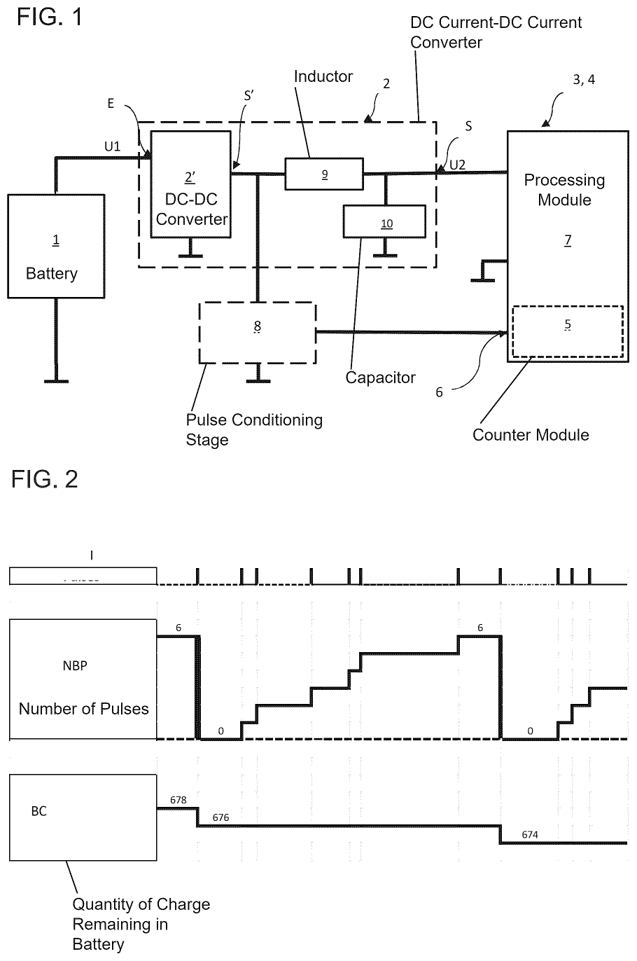

FIG. 1 illustrates schematically the measurement device according to the invention. The measurement device notably includes the DC current-DC current converter 2, the pulse conditioning stage 8 and the control unit 3 in the form of the microcontroller 4 including the counter module 5 and the processing module 7. The measurement device according to the invention differs from the known prior art notably by the presence of the pulse-conditioning stage 8 and of the counter module 5 which is integrated into the microcontroller 4, preferably originally. The DC current-DC current converter 2 is electrically connected at its input E to a battery 1 which does not form part of the measurement device. The DC current-DC current converter 2 is electrically connected to the control unit 3 by the output S via its inductor 9 and its capacitor 10 for supplying power to the control unit 3 at the output voltage U2. The chip of the DC/DC converter 2′ of the DC current-DC current converter 2 is furthermore electrically connected at its additional output S′ to the pulse conditioning stage 8 in order to enable the clipping of the pulse-train signal. The pulse conditioning stage 8 is electrically connected to the control unit 3 and in particular to the counter input 6 of the counter module 5 for determining the number of pulses, the number of pulses obtained being used to determine the quantity of charge remaining BC in the at least one battery 1 for the measurement duration, as has been previously described.

The correspondence between a certain quantity of charges NBC delivered by the battery or batteries 1 and the corresponding number of pulses counted NBP is known for the operation of the invention. It is possible to use default values for the latter, but the expected results delivered by the invention are more accurate after a calibration at the factory and if the calibration parameter NC is determined.

In order to explain examples of operation of the processing module 7, the variable BCinitial is defined, which corresponds to the number of charges remaining in the battery or batteries 1, adjusted at the factory with the value for a new battery or batteries. All the numerical values hereinafter NBPC=7, NBCC=2 and BCinitial=678 and in the figures are fictitious and are only provided for the understanding.

According to a first possibility illustrated in FIG. 2, as soon as the battery or batteries 1 deliver current, pulses I are generated and counted by the counter module 5 inside the microcontroller 4. Each time that the counter module 5 reaches the value NBPC, it is reset to 0 and the value BC is reduced by NBCC. With this principle, the processing module 7 is capable of reacting very swiftly. This processing principle requires a fast reactivity of the microcontroller 4 but minimal computing resources.

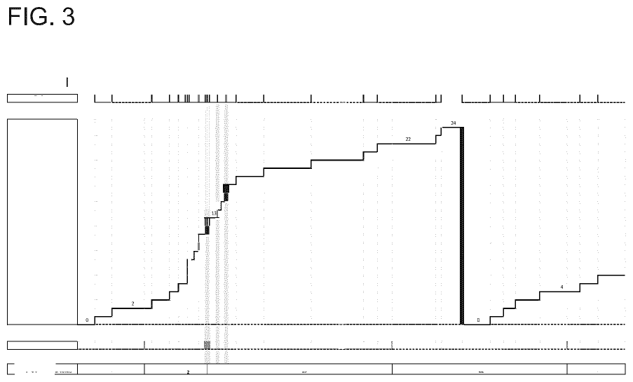

According to a second possibility illustrated in FIG. 3, as soon as the battery or batteries 1 deliver current, pulses I are generated and counted by the counter module 5 inside the microcontroller 4. The counter module 5 is never reset to 0 and simply increases up to its maximum capacity and automatically returns to 0 after. The processing module 7 simply has to occasionally read the counter module 5 and to process the result as follows:
divide the number of pulses obtained at a given time Ni, to which the remainder of the division of the preceding iteration is added, by the number of calibration pulses NBPC, then
subtract from the preceding value of the quantity of charge remaining BC in the at least one battery 1 the calibration quantity of charge NBCC multiplied by the integer obtained during the division,
then keep the remainder of the division for the next iteration.

The processing principle requires a few more computing resources from the microcontroller 4 but is not dependent on time.

One example of a processing based on FIG. 3 is described hereinabove:

### Reading N°1

New reading of the counter module=2
Preceding reading of the counter module=0
New number of pulses seen=2−0=2
Remainder from the preceding processing=0

$$\\ Calculate ( New number of pulses seen + Remainder from the preceding processing ) / NBPC = ( 2 + 0 ) / 7.$$

$$\\ The Integer part is obtained = 0 and the Remainder = 2$$

Subtract (NBCC*Integer part) from BC

The quantity of charge remaining is obtained BC=678-2*0=678

### Reading N°2

New reading of the counter module=13
Preceding reading of the counter module=2
New number of pulses seen=13−2=11
Remainder from the preceding processing=2

$$\\ Calculate ( New number of pulses seen + Remainder from the preceding processing ) / NBPC = ( 11 + 2 ) / 7.$$

$$\\ The Integer part is obtained = 1 and the Remainder = 6$$

Subtract (NBCC*Integer part) from BC

The quantity of charge remaining is obtained BC=678-2*1=676

### Reading N°3

New reading of the counter module=22
Preceding reading of the counter module=13
New number of pulses seen=22−13=9
Remainder from the preceding processing=6

$$\\ Calculate ( New number of pulses seen + Remainder from the preceding processing ) / NBPC = ( 9 + 6 ) / 7.$$

$$\\ The Integer part is obtained = 2 and the Remainder = 1$$

Subtract (NBCC*Integer part) from BC

The quantity of charge remaining is obtained BC=676-2*2=672

### Reading N° 4

New reading of the counter module=4
Preceding reading of the counter module=22
New number of pulses seen=4−(22-25)=7 (maximum capacity of the counter=25)
Remainder from the preceding processing=1

$$\\ Calculate ( New number of pulses seen + Remainder from the preceding processing ) / NBPC = ( 7 + 1 ) / 7.$$

$$\\ The Integer part is obtained = 1 and the Remainder = 1$$

Subtract (NBCC*Integer part) 2 from BC

The quantity of charge remaining is obtained BC=672-2*1=670

It goes without saying that the invention is not limited to the embodiments described and shown in the appended drawings. Modifications remain possible, notably from the point of view of the constitution of the various elements or by substitution of technical equivalents, without however straying from the scope of protection of the invention.

1. A device for measuring the quantity of charge remaining in at least one battery, the device comprising:
a switch-mode DC current-DC current converter configured for converting an input voltage coming from the at least one battery into an output voltage and supplying a pulse-train signal at an additional output, said DC current-DC current converter being configured for extracting a quantity of charge from the at least one battery for a measurement duration corresponding to a number of pulses of the pulse-train signal;
a control unit electrically connected to said DC current-DC current converter, said control unit including at least one microcontroller;
said at least one microcontroller including a counter module having a counter input and said at least one microcontroller including a processing module electrically connected to said counter module;
a pulse conditioning stage electrically connected to said additional output and to said counter input and being configured for clipping the pulse-train signal in such a manner as to condition the pulse-train signal to be compatible with said counter input;
said counter module being configured for counting the number of pulses of the pulse-train signal conditioned by said pulse conditioning stage; and
said processing module being configured, at least using the number of pulses obtained by said counter module, for determining the quantity of charge remaining in the at least one battery for a measurement duration.

2. The measurement device according to claim 1, wherein said pulse conditioning stage includes at least one passive analogue circuit with no control logic.

3. The measurement device according to claim 2, wherein said pulse conditioning stage includes at least one voltage clipper.

4. The measurement device according to claim 1, which further comprises a memory electrically connected to said processing module, said processing module including a calibration parameter pre-recorded to a calibration operation in said memory, the calibration parameter corresponding to a number of calibration pulses for extracting a calibration quantity of charge from the at least one battery.

5. The measurement device according to claim 4, wherein the calibration parameter is pre-recorded consecutively to the calibration operation.

6. The measurement device according to claim 4, wherein for the measurement duration and in an iterative manner, said counter module is configured so that each time that a value of the number of pulses obtained reaches the number of calibration pulses, information about reaching the number of calibration pulses is communicated to said processing module, in such a manner that said processing module is configured for subtracting the calibration quantity of charge from a preceding value of the quantity of charge remaining in the at least one battery.

7. The measurement device according to claim 4, wherein for the measurement duration and in an iterative manner, said processing module is configured for reading a value of the number of pulses obtained at a given time, said processing module is configured for dividing the number of pulses obtained at a given time, to which a remainder of the division from a preceding iteration is added, by the number of calibration pulses, then subtracting from the preceding value of the quantity of charge remaining in the at least one battery the calibration quantity of charge multiplied by an integer obtained during the division, then keeping the remainder of the division for a next iteration.

8. The measurement device according to claim 1, which further comprises a wireless communications unit electrically connected to said control unit.

9. The measurement device according to claim 8, wherein said wireless communications unit is at least one of a radiofrequency or NFC unit.

10. The measurement device according to claim 1, which further comprises a human-machine interface electrically connected to said control unit.

11. A fluid and/or thermal energy meter, comprising the at least one battery and the device according to claim 1 for measuring the quantity of charge remaining in the at least one battery.

12. A clipper module, comprising the at least one battery and the device according to claim 1 for measuring the quantity of charge remaining in the at least one battery.
